(19) United States
(12) Patent Application Publication
(10) Pub. No.: US 2025/0107131 A1
(43) Pub. Date: Mar. 27, 2025

(54) GATE STRUCTURE OF SEMICONDUCTOR DEVICE

(71) Applicant: TEXAS INSTRUMENTS INCORPORATED, Dallas, TX (US)

(72) Inventors: Sandeep R. Bahl, Palo Alto, CA (US); Ujwal Radhakrishna, San Jose, CA (US); Chang Soo Suh, Allen, TX (US)

(21) Appl. No.: 18/472,329

(22) Filed: Sep. 22, 2023

(51) Int. Cl. H01L 29/778; H01L 29/08; H01L 29/20; H01L 29/66

(52) U.S. Cl. CPC H10D 30/475; H10D 30/015; H10D 62/151; H10D 62/8503

(57) ABSTRACT

The present disclosure generally relates to a conductive layer in a gate structure of a semiconductor device. The conductive layer may be a silicon layer. An example is a semiconductor device. The semiconductor device includes a channel layer, a barrier layer, a gate layer, and a silicon layer. The channel layer is over a semiconductor substrate. The barrier layer is over the channel layer. The gate layer is over the barrier layer. The silicon layer is over and contacts the gate layer.

### BACKGROUND

A type of semiconductor device is a high electron mobility transistor (HEMT). A HEMT typically employs different semiconductor materials to form a heterojunction, where a channel may be formed near the heterojunction and between a source region and a drain region. A HEMT may support a high speed operation, which makes HEMTs attractive for high frequency applications, among others.

### SUMMARY

An example described herein is a semiconductor device. The semiconductor device includes a channel layer, a barrier layer, a gate layer, and a silicon layer. The channel layer is over a semiconductor substrate. The barrier layer is over the channel layer. The gate layer is over the barrier layer. The silicon layer is over and contacts the gate layer.

Another example is a method. A channel layer is formed over a semiconductor substrate. A barrier layer is formed over the channel layer. A gate layer is formed over the barrier layer. A silicon layer is formed over and contacting the gate layer.

A further example is a semiconductor device. The semiconductor device includes a high electron mobility transistor (HEMT). The HEMT includes a channel layer, a barrier layer, and a gate structure. The channel layer is over a semiconductor substrate. The barrier layer is over the channel layer. The gate structure is over the barrier layer. The gate structure includes a semiconductor layer and a silicon layer over and contacting the semiconductor layer. The semiconductor layer includes a semiconductor material different from silicon.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device according to some examples.

FIG. 2 is a cross-sectional view of a semiconductor device according to some examples.

FIGS. 3, 4, and 5 are cross-sectional views of the semiconductor device of FIG. 1 at various stages of a first portion of a method of manufacturing according to some examples.

FIGS. 6, 7, 8, 9, 10, and 11 are cross-sectional views of the semiconductor device of FIG. 2 at various stages of a second portion of a method of manufacturing according to some examples.

FIGS. 12 and 13 are cross-sectional views of the semiconductor device of FIG. 2 at various stages of a third portion of a method of manufacturing according to some examples.

FIGS. 14 and 15 are cross-sectional views of a semiconductor device at various stages of a fourth portion of a method of manufacturing according to some examples.

FIGS. 16, 17, 18 and 19 are cross-sectional views of a semiconductor device at various stages of a fifth portion of a method of manufacturing according to some examples.

FIGS. 20, 21, and 22 are cross-sectional views of a semiconductor device at various stages of a sixth portion of a method of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to a silicon layer (or a conductive layer) in a gate structure of a semiconductor device. Some examples include a semiconductor device that includes a channel layer over a semiconductor substrate, a barrier layer over the channel layer, a gate layer over the barrier layer, and a silicon layer over and contacting the gate layer. In some examples, the semiconductor device is or includes a high electron mobility transistor (HEMT), such as an enhancement mode HEMT. The gate layer and the silicon layer may form at least part of a gate structure of the semiconductor device. The silicon layer may be formed with the gate layer in a self-aligned process and may be a highly doped, conductive polysilicon layer. Incorporating a silicon layer in a gate structure may achieve improved gate depletion during operation, decoupling of a parasitic capacitance, and retention of a high energy barrier height Schottky junction in or at the gate structure of the semiconductor device. Other benefits and advantages may be achieved.

Various examples are described subsequently. Although the specific examples may illustrate various aspects of the above generally described features, examples may incorporate any combination of the above generally described features (which are described in more detail in examples below).

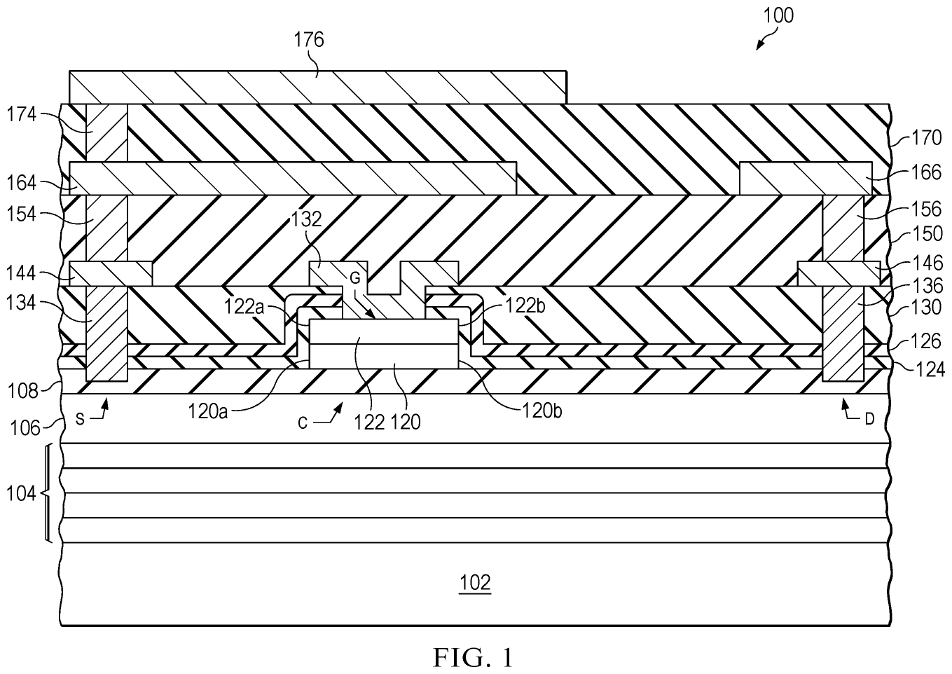

FIG. 1 is a cross-sectional view of a semiconductor device 100 according to some examples. The semiconductor device 100, in this example, is or includes a HEMT. Further, the semiconductor device 100 may be or include an enhancement mode HEMT. Other examples may be or include other types of devices.

FIG. 1 shows a semiconductor substrate 102 and one or more transition layers 104 over and on the semiconductor substrate 102. A channel layer 106 is over and on the uppermost transition layer 104. A barrier layer 108 is over and on the channel layer 106.

The semiconductor substrate 102 may be a bulk semiconductor substrate, a semiconductor-on-insulator (SOI) substrate, or any other appropriate substrate. For example, the semiconductor substrate 102 may be or include a bulk silicon wafer. The transition layer(s) 104 may include any number of layers of any materials that are configured to accommodate lattice mismatch between the semiconductor substrate 102 and the channel layer 106 (e.g., to reduce or minimize lattice defect generation and/or propagation in the channel layer 106). For example, the transition layer(s) 104 may have a gradient concentration of one or more elements in a direction normal to the top surface of the semiconductor substrate 102.

The channel layer 106 is configured, possibly in conjunction with the barrier layer 108, to conduct and confine charge carriers (such as electrons) within two dimensions. In some examples, the channel layer 106 is configured to include a two-dimensional electron gas (2DEG). The 2DEG may be formed by energy band bending resulting from the barrier layer 108 being over and on the channel layer 106 and their differences in polarization. In some examples, the channel layer 106 includes a gallium nitride (GaN) layer and, in such examples, may be referred to as a GaN channel layer. In some examples, the material of the channel layer 106 is or includes an unintentionally doped material, such as a material doped by diffusion of dopants from another layer or from the background during the layer growth. The barrier layer 108, in some examples, may be or include an aluminum gallium nitride (AlGaN) layer and, in such examples, may be referred to as an AlGaN barrier layer. More generally, in some examples, the channel layer 106 may be or include indium aluminum gallium nitride (InᵢAlⱼGa₁₋ᵢ₋ⱼN) (where 0≤i≤1, 0≤j≤1, and 0≤i+j≤1), and the barrier layer 108 may be or include indium aluminum gallium nitride (InₖAlₗGa₁₋ₖ₋ₗN) (where 0<k≤1, 0≤l≤1, and 0≤k+l≤1). Other materials may be implemented for the channel layer 106 and/or the barrier layer 108.

A gate layer 120 is over and on an upper surface of the barrier layer 108. In some examples, the gate layer 120 is or includes a semiconductor layer of a semiconductor material that is different from silicon. Further, the gate layer 120 is doped with a dopant. In some examples, the gate layer 120 is doped with a p-type dopant. In some examples, the gate layer 120 may be or include a gallium nitride (GaN) layer, or more generally, indium aluminum gallium nitride (InₘAlₙGa₁₋ₘ₋ₙN) (where 0≤m<1, 0≤n<1, and 0m+n≤1), and the dopant with which the gate layer 120 is doped is a p-type dopant, which may be or include magnesium (Mg), carbon (C), zinc (Zn), the like, or a combination thereof. In examples in which the gate layer 120 is gallium nitride (GaN) doped with a p-type dopant, the gate layer 120 may be referred to as a p-doped GaN (pGaN) layer. Further, in examples in which the gate layer 120 is gallium nitride (GaN) doped with a magnesium, the gate layer 120 may be referred to as a magnesium doped gallium nitride (GaN: Mg) layer. In some examples, a concentration of the dopant in the gate layer 120 may be less than 5×10²⁰ cm⁻³. In other examples, a concentration of the dopant in the gate layer 120 may be less than 1×10²¹ cm⁻³. As used herein, a concentration of a dopant includes a chemical concentration—e.g., a concentration of a dopant in a semiconductor layer, which may be determined by secondary ion mass spectrometry (SIMS) in some cases. The Mg or p-type dopant concentration profile could be uniform throughout the p-type GaN layer or may increase or decrease from the bottom to top. The dopant concentration profile could also be high at top and bottom of the layer and lower in the bulk of the layer. Other materials, dopants, and/or concentrations may be implemented in other examples.

A silicon layer 122 is over and on (e.g., contacting) the gate layer 120. The silicon layer 122, in some examples, is or includes polysilicon. Further, in some examples, the silicon layer 122 is doped with a dopant, such as with a p-type dopant. The dopant with which the silicon layer 122 is doped may be a same conductivity type (e.g., p-type) as the dopant with which the gate layer 120 is doped. An example p-type dopant of the silicon layer 122 includes boron (B) or the like. In some examples, a concentration of the dopant (e.g., p-type dopant) in the silicon layer 122 may be equal to or greater than 1×10¹⁹ cm⁻³, and more particularly, equal to or greater than 1×10²⁰ cm⁻³(e.g., 2×10²⁰ cm⁻³). In some examples, a concentration of the dopant in the silicon layer 122 may be less than 5×10²¹ cm⁻³. In some examples, a concentration of the dopant (e.g., p-type dopant, such as boron (B)) in the silicon layer 122 is at least two (2) times greater than (such as from two (2) to ten (10) or one hundred (100) times greater than) a concentration of the dopant (e.g., p-type dopant, such as magnesium (Mg), carbon (C), or zinc (Zn)) in the gate layer 120. The silicon layer 122, in some examples, forms a Schottky junction with the gate layer 120 at the interface of the gate layer 120 and the silicon layer 122. In other examples, another conductive layer may be in the place of or included with (e.g., over and on) the silicon layer 122. Such other conductive layer may be or include a refractory metal (e.g., chromium, molybdenum, tantalum, tungsten, titanium, hafnium, or iridium), a conductive ceramic (e.g., indium tin oxide (ITO), or any other front-end-of-the-line (FEOL) compatible conductive material.

In the illustrated example of FIG. 1, the silicon layer 122 has sidewall surfaces that vertically align with respective sidewall surfaces of the gate layer 120. As illustrated, a source-side sidewall surface 122a of the silicon layer 122 vertically aligns with a source-side sidewall surface 120a of the gate layer 120, and a drain-side sidewall surface 122b of the silicon layer 122 vertically aligns with a drain-side sidewall surface 120b of the gate layer 120.

The semiconductor device 100 includes a drain region D, a channel region C, a source region S, and a gate structure G. The gate structure G includes the gate layer 120 and the silicon layer 122. The channel region C is in the channel layer 106 underlying the gate structure G. The channel region C is laterally between the drain region D and the source region S, which are also in the channel layer 106.

A first conformal dielectric layer 124 is conformally over and on the barrier layer 108, the gate layer 120, and the silicon layer 122, and a second conformal dielectric layer 126 is conformally over and on first conformal dielectric layer 124. The first conformal dielectric layer 124 is conformally over and on an upper surface of the barrier layer 108, along sidewall surfaces 120a, 120b, 122a, 122b of the gate layer 120 and the silicon layer 122, and over and on an upper surface of the silicon layer 122. The first conformal dielectric layer 124 and the second conformal dielectric layer 126 may be or include any appropriate dielectric material, such as silicon nitride, silicon oxide, silicon oxynitride, aluminum nitride, aluminum oxide, aluminum oxynitride, the like, or a combination thereof.

A first dielectric layer 130 is over and on the second conformal dielectric layer 126. The first dielectric layer 130 may be a single dielectric layer or may include multiple dielectric layers of a same dielectric material or different dielectric materials. For example, the first dielectric layer 130 may include a silicon nitride, a silicon oxide-based material (such as a phosphosilicate glass (PSG) or a tetraethyl orthosilicate (TEOS) oxide), polytetrafluoroethylene, or the like.

A gate contact 132 is through an opening through the first dielectric layer 130, the second conformal dielectric layer 126, and the first conformal dielectric layer 124 to the silicon layer 122. The gate contact 132 is over and contacts the silicon layer 122. A portion of the gate contact 132 may be overlying the first dielectric layer 130 proximate to the opening through which the gate contact 132 contacts the silicon layer 122. The gate contact 132 may be or include a metal, such as titanium (Ti), titanium tungsten (TiW), titanium nitride (TiN), nickel (Ni), platinum (Pt), tantalum nitride (TaN), aluminum (Al), copper (Cu), tungsten (W), gold (Au), iridium (Ir), tantalum (Ta), the like, or a combination thereof (such as including a stack including layers of different metal layers and/or an alloy, which may be an alloy as-deposited and/or distinct layers reacted together by, e.g., an anneal). The gate contact 132 may be or include a metal that forms an ohmic junction with the silicon layer 122 at the interface of the gate contact 132 and the silicon layer 122.

A source contact 134 extends through the first dielectric layer 130, the second conformal dielectric layer 126, and the first conformal dielectric layer 124 and into and contacting the barrier layer 108 on the source region S, and a drain contact 136 extends through the first dielectric layer 130, the second conformal dielectric layer 126, and the first conformal dielectric layer 124 and into and contacting the barrier layer 108 on the drain region D. The source contact 134 and the drain contact 136 are electrically coupled to the source region S and the drain region D, respectively, in the channel layer 106. The gate structure G (including the gate layer 120 and the silicon layer 122) is laterally between the source contact 134 and the drain contact 136. Metal lines 144, 146 in a first metal layer are over and on the contacts 134, 136, respectively, and an upper surface of the first dielectric layer 130. The contacts 134, 136 may each include one or more metal-barrier and/or adhesion layers (e.g., titanium nitride (TiN), tantalum nitride (TaN), titanium (Ti), the like, or a combination thereof) in a respective opening through the dielectric layers 130, 126, 124, and a fill metal (e.g., aluminum (Al), copper (Cu), tungsten (W), the like, or a combination thereof) over and/or on the metal-barrier and/or adhesion layer(s). The metal lines 144, 146 may each include one or more metal-barrier and/or adhesion layers (e.g., titanium nitride (TiN), tantalum nitride (TaN), titanium (Ti), the like, or a combination thereof) and a bulk metal (e.g., aluminum (Al), copper (Cu), the like, or a combination thereof) over and/or on the metal-barrier and/or adhesion layer(s).

As illustrated by methods described below, in some examples, the gate contact 132 may be or include a same metal(s) as the source contact 134 and the drain contact 136. For example, the contacts 132, 134, 136 may be or include a same aluminum-based metal. In some examples, the gate contact 132 may be or include metal(s) different from the metal(s) of the source contact 134 and the drain contact 136. For example, the source contact 134 and the drain contact 136 may be or include an aluminum-based metal, and the gate contact 132 may be or include titanium nitride (TiN), titanium tungsten (TiW), or a combination thereof.

A second dielectric layer 150 is over and on the first dielectric layer 130, the gate contact 132, and the metal lines 144, 146. The second dielectric layer 150 may be a single dielectric layer or may include multiple dielectric layers of a same dielectric material or different dielectric materials. For example, the second dielectric layer 150 may include a silicon nitride or a silicon oxide-based material, such as a PSG, and may further include one or more etch stop layers, such as silicon nitride (SiN) or the like.

Metal vias 154, 156 extend through the second dielectric layer 150 and contact the metal lines 144, 146, respectively. A metal field plate 164 and a metal line 166 in a second metal layer are over and on the metal vias 154, 156, respectively, and an upper surface of the second dielectric layer 150. The metal field plate 164 extends laterally from over the source region S to over an access region between the channel region C and the drain region D. The metal vias 154, 156 may each include one or more metal-barrier and/or adhesion layers (e.g., titanium nitride (TiN), tantalum nitride (TaN), titanium (Ti), the like, or a combination thereof) in a respective opening through the second dielectric layer 150, and a fill metal (e.g., tungsten (W), copper (Cu), aluminum (Al), the like, or a combination thereof) over and/or on the metal-barrier and/or adhesion layer(s). The metal field plate 164 and a metal line 166 may each include one or more metal-barrier and/or adhesion layers (e.g., titanium nitride (TiN), tantalum nitride (TaN), titanium (Ti), the like, or a combination thereof) and a bulk metal (e.g., aluminum (Al), copper (Cu), the like, or a combination thereof) over and/or on the metal-barrier and/or adhesion layer(s).

A third dielectric layer 170 is over and on the second dielectric layer 150 and the metal field plate 164 and a metal line 166. The third dielectric layer 170 may be a single dielectric layer or may include multiple dielectric layers of a same dielectric material or different dielectric materials. For example, the third dielectric layer 170 may include a silicon nitride or a silicon oxide-based material, such as a PSG, and may further include one or more etch stop layers, such as silicon nitride (SiN) or the like.

A metal via 174 extends through the third dielectric layer 170 and contacts the metal field plate 164. A metal field plate 176 in a third metal layer is over and on the metal via 174 and an upper surface of the third dielectric layer 170. The metal field plate 176 extends laterally from over the source region S to over an access region between the channel region C and the drain region D, which may be laterally extending further than the metal field plate 164. The metal via 174 may include one or more metal-barrier and/or adhesion layers (e.g., titanium nitride (TiN), tantalum nitride (TaN), titanium (Ti), the like, or a combination thereof) in a respective opening through the third dielectric layer 170, and a fill metal (e.g., tungsten (W), copper (Cu), aluminum (Al), the like, or a combination thereof) over and/or on the metal-barrier and/or adhesion layer(s). The metal field plate 176 may include one or more metal-barrier and/or adhesion layers (e.g., titanium nitride (TiN), tantalum nitride (TaN), titanium (Ti), the like, or a combination thereof) and a bulk metal (e.g., aluminum (Al), copper (Cu), the like, or a combination thereof) over and/or on the metal-barrier and/or adhesion layer(s).

Additional dielectric layers and metal layers may be formed over and on the third dielectric layer 170. The first dielectric layer 130, second dielectric layer 150, third dielectric layer 170, additional dielectric layers, first metal layer, second metal layer, third metal layer, and additional metal layers may form an interconnect structure. Metal lines in neighboring metal layers may be electrically coupled by metal vias.

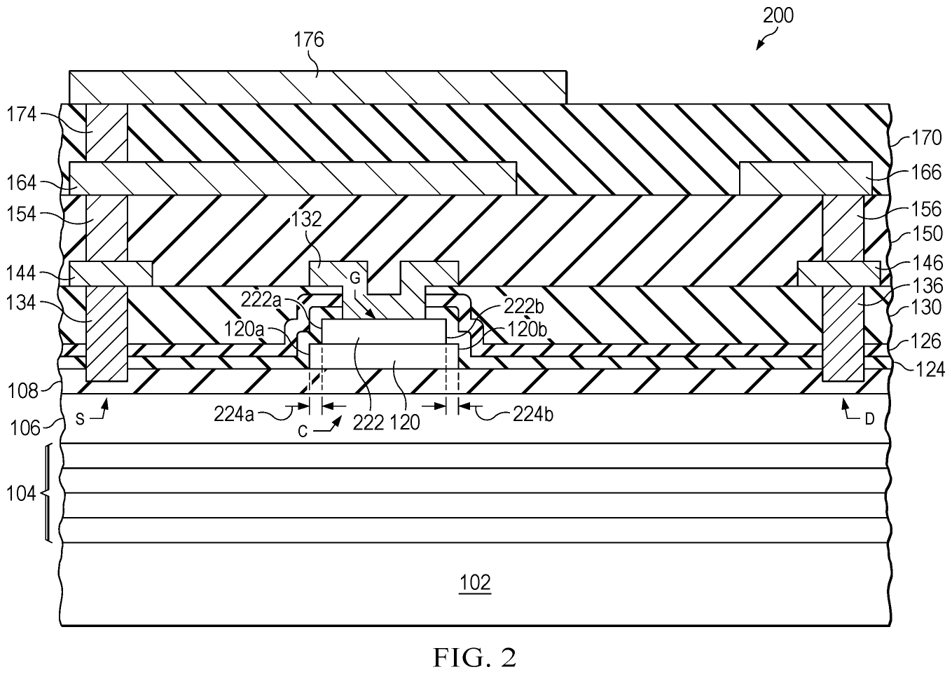

FIG. 2 is a cross-sectional view of a semiconductor device 200 according to some examples. The semiconductor device 200, in this example, is or includes a HEMT. Further, the semiconductor device 200 may be or include an enhancement mode HEMT. Other examples may be or include other types of devices.

The semiconductor device 200 of FIG. 2 is like the semiconductor device 100 of FIG. 1, except that the silicon layer 122 of FIG. 1 is replaced with a silicon layer 222. In other examples, another conductive layer may be in the place of or included with (e.g., over and on) the silicon layer 222. Such other conductive layer may be or include a refractory metal, a conductive ceramic, or any other FEOL compatible conductive material.

The silicon layer 222 is like the silicon layer 122 of FIG. 1 except that lateral sidewall surfaces of the silicon layer 222 are laterally offset inwardly (with respect to the gate layer 120) from the respective sidewall surfaces of the gate layer 120. As illustrated, a source-side sidewall surface 222a of the silicon layer 222 is laterally offset by a lateral distance 224a from a source-side sidewall surface 120a of the gate layer 120, and a drain-side sidewall surface 222b of the silicon layer 222 is laterally offset by a lateral distance 224b from a drain-side sidewall surface 120b of the gate layer 120. The lateral distances 224a, 224b may each be 50 nm or more. As a result of the lateral offset of the silicon layer 222, the first conformal dielectric layer 124 is over and on an upper surface of the gate layer 120 where the sidewall surfaces 222a, 222b of the silicon layer 222 are laterally offset from the sidewall surfaces 120a, 120b of the gate layer 120.

According to some examples, incorporating a silicon layer 122, 222 and/or another conductive layer as described above with respect to FIGS. 1 and 2 may achieve improved gate depletion during operation, decoupling of a parasitic capacitance, and retention of a high energy barrier height Schottky junction in or at the gate structure G. In processing, a photolithography process used to form an opening in which a gate contact is formed generally has a given tolerance. Circuit designers usually design a layout such that this opening is laterally displaced at least that tolerance from each sidewall surface of the gate layer. Absent the silicon layer 122, 222 and/or another conductive layer, assuming ideal alignment, the opening, and hence, the gate contact, does not contact the upper surface of the gate layer from sidewall surfaces corresponding to a source side and a drain side for the tolerance distance. Assuming non-ideal alignment, the opening, and hence, the gate contact, does not contact the upper surface of the gate layer for greater than the tolerance from at least one sidewall surface. Because of this built-in processing tolerance, gate depletion may be non-uniform, such that a depletion gradient occurs from where the gate contact makes contact with the gate layer. Further, a gate contact may be formed contacting a gate layer and formed where some dielectric is disposed between portions of the gate contact and the gate layer. A parasitic capacitance forms between these portions. The non-uniform gate depletion and parasitic capacitance may have an adverse effect on the drain current through the semiconductor device.

Implementing the silicon layer 122, 222 and/or another conductive layer may form a conductive layer that is self-aligned with the gate layer 120. The silicon layer 122, 222 may be highly doped (e.g., 2×10²⁰ cm⁻³) which may form a low resistance, highly conductive node. Being self-aligned, the silicon layer 122, 222 may obviate the alignment tolerance for forming a gate contact and may permit more uniform depletion through the gate layer 120—e.g., across the lateral dimension of the gate layer 120 between the source region S and the drain region D. Further, the silicon layer 122, 222 may form an ohmic contact with the gate contact 132 such that the silicon layer 122, 222 and gate contact 132 are at a same electrical potential and/or are a same electrical node. Hence, the presence of the silicon layer 122, 222 may decouple a parasitic capacitance between the gate contact 132 and the gate layer 120. Compared to a semiconductor device without one of the silicon layers 122, 222, a semiconductor device 100, 200 with the silicon layer 122, 222 may achieve an approximately 45% increase in drain current. Although, conceivably, a metal layer may be formed in the place of the silicon layer 122 to achieve a similar benefit, forming such a metal layer may be incompatible with subsequent processing. For example, deposition of one or more layers subsequent to the formation of such a metal layer (e.g., in a low pressure chemical vapor deposition (LPCVD)) may require a process temperature to be too high to maintain the integrity of the metal layer. However, the silicon layer 122, 222 (or a refractory metal, a conductive ceramic, or any other front-end-of-the-line (FEOL) compatible materials) may be compatible with such processes, which may be a complementary metal-oxide-semiconductor (CMOS) process.

Further, implementing the silicon layer 122, 222 and/or another conductive layer may maintain a high energy barrier height Schottky junction in the current loop that includes the gate structure G. The silicon layer 122, 222 may be doped such that energy bands of the silicon layer 122, 222 and the gate layer 120 form a high energy barrier height Schottky junction. A junction between the silicon layer 122, 222 and the gate contact 132 may be ohmic. The Schottky junction may result in low leakage current from the gate structure G.

In some implementations, particularly high voltage applications, the silicon layer 222 of FIG. 2 and/or another conductive layer may reduce an electric field at a corner of the gate layer 120. The sidewall surfaces 222a, 222b of the silicon layer 222 being laterally offset from the sidewall surfaces 120a, 120b of the gate layer 120 may reduce the electric field experienced at the corners of the gate layer 120 at the upper surface of the barrier layer 108. This reduced electric field may reduce leakage current and improve time dependent dielectric breakdown (TDDB) of the semiconductor device 200.

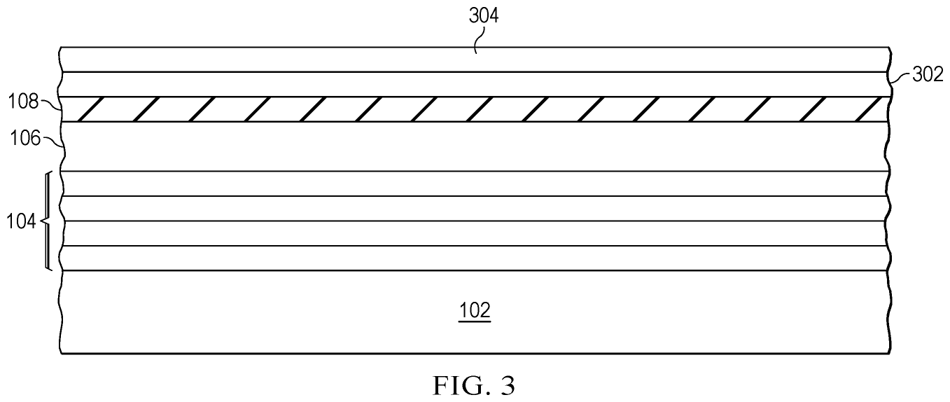

FIGS. 3 through 5 illustrate cross-sectional views of the semiconductor device 100 of FIG. 1 at various stages of a first portion of a method of manufacturing according to some examples. The processing shown in FIGS. 3 through 5 shows, among other things, the formation of the gate structure G of the semiconductor device 100 of FIG. 1.

Referring to FIG. 3, one or more transition layers 104 are formed over and on a semiconductor substrate 102. The channel layer 106 is formed over and on the transition layer(s) 104, and the barrier layer 108 is formed over and on the channel layer 106. In some examples, the transition layer(s) 104, channel layer 106, and barrier layer 108 may be formed by using any appropriate deposition process, which may further be an epitaxial growth process. For example, the transition layer(s) 104, channel layer 106, and barrier layer 108 may each be epitaxially grown using metal-organic chemical vapor deposition (MOCVD), molecular beam epitaxy (MBE), LPCVD, or another epitaxy process. The materials of the semiconductor substrate 102, transition layer(s) 104, channel layer 106, and barrier layer 108 may be as described previously.

Further, a gate layer 302 is formed over and on the barrier layer 108. In some examples, the gate layer 302 may be epitaxially grown, such as by MOCVD, MBE, LPCVD, plasma enhanced chemical vapor deposition (PECVD), atomic layer epitaxy, or another epitaxy process. The gate layer 302 may be doped in situ during deposition (e.g., epitaxial growth) or by implantation subsequent to deposition. The materials of the gate layer 302, any dopant, and any concentration of a dopant may be as described previously.

A silicon layer 304 is formed over and on the gate layer 302. In some examples, the silicon layer 304 may be deposited by PECVD, LPCVD, atomic layer deposition (ALD), the like, or a combination thereof. In some examples, the silicon layer 304 may be deposited as amorphous silicon, and as a result of subsequent processing, may be crystallized into polycrystalline silicon. In some examples, the silicon layer 304 may be deposited as polycrystalline silicon. The silicon layer 304 may be doped in situ during deposition or may be implanted with dopants after deposition. The dopant and concentration of the dopant may be as described previously. Another conductive layer may be formed in the place of or with (e.g., over and on) the silicon layer 304.

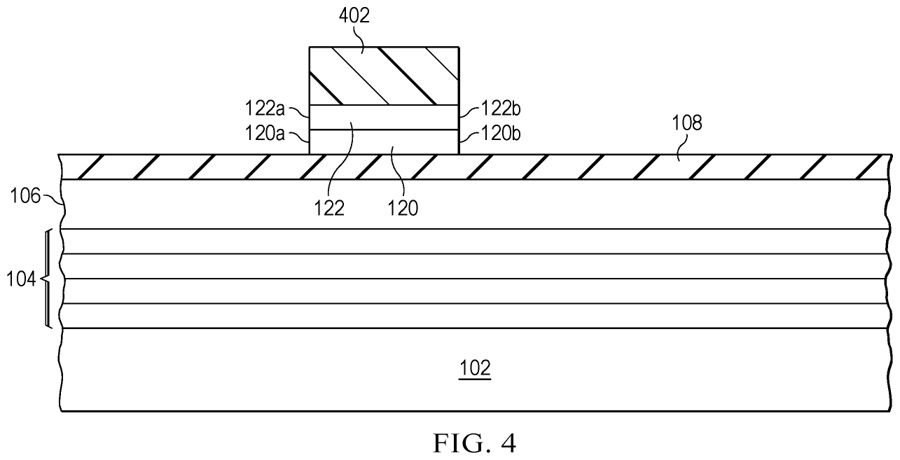

Referring to FIG. 4, the silicon layer 304 and the gate layer 302 are patterned into a patterned silicon layer 122 and a patterned gate layer 120, respectively. The silicon layer 304 and the gate layer 302 may be patterned using appropriate photolithography and etch processes. For example, to pattern the silicon layer 304 and the gate layer 302, a photoresist 402 is deposited (e.g., by spin-on) on or over the semiconductor substrate 102 (e.g., on or over the silicon layer 304) and patterned using photolithography. The photoresist 402 is patterned to remain in an area corresponding to an area where the gate structure G is to be formed. With the patterned photoresist 402, an etch process, such as an anisotropic etch like a reactive ion etch (RIE) or the like, is performed, using the patterned photoresist 402 as a mask, to pattern the silicon layer 304 and gate layer 302 into the patterned silicon layer 122 and patterned gate layer 120. After the etch process, the photoresist 402 is removed, such as by ashing. Patterning as described with respect to FIG. 4 forms the sidewall surfaces 122a, 122b of the silicon layer 122 that are vertically aligned with the respective sidewall surfaces 120a, 120b of the gate layer 120.

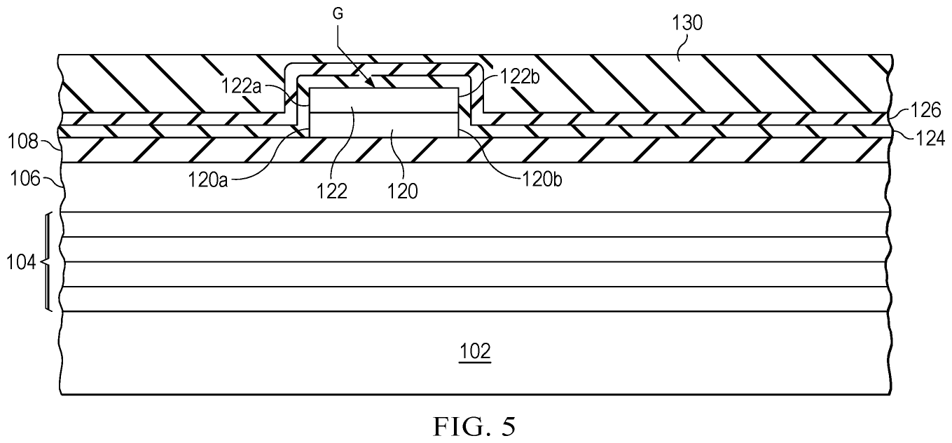

Referring to FIG. 5, a first conformal dielectric layer 124 is formed over and on the silicon layer 122 and barrier layer 108 and along the sidewall surfaces 120a, 120b, 122a, 122b of the gate layer 120 and silicon layer 122. The first conformal dielectric layer 124 is conformally deposited over and on the barrier layer 108, along the sidewall surfaces 120a, 120b, 122a, 122b of the gate layer 120 and silicon layer 122, and over and on an upper surface of the silicon layer 122. The first conformal dielectric layer 124 may be formed using any appropriate deposition process, such as LPCVD, ALD, or the like. The material of the first conformal dielectric layer 124 may be as described above.

A second conformal dielectric layer 126 is formed over and on the first conformal dielectric layer 124. The second conformal dielectric layer 126 is conformally deposited over and on the first conformal dielectric layer 124. The second conformal dielectric layer 126 may be formed using any appropriate deposition process, such as PECVD, ALD, or the like. The material of the second conformal dielectric layer 126 may be as described above.

A first dielectric layer 130 is formed over and on the second conformal dielectric layer 126. The first dielectric layer 130 may be deposited using any appropriate deposition process, such as PECVD, LPCVD, or the like. The material(s) of the first dielectric layer 130 may be as described above. The first dielectric layer 130 may be planarized, such as by a chemical mechanical polish (CMP).

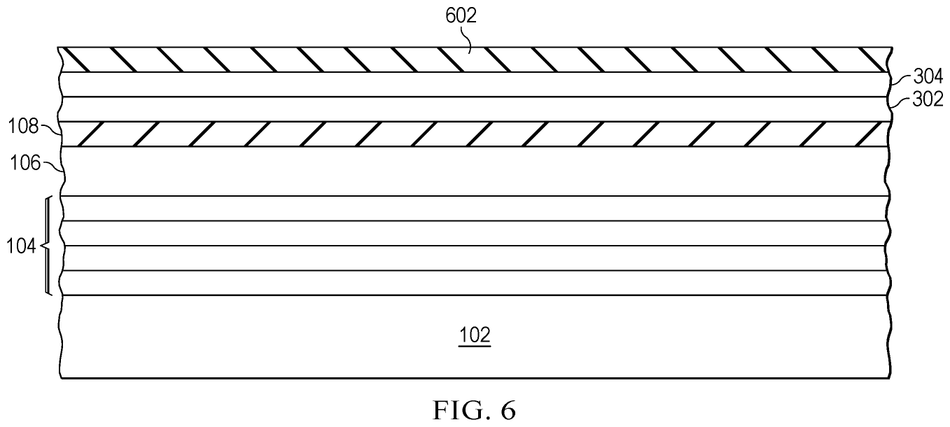

FIGS. 6 through 11 illustrate cross-sectional views of the semiconductor device 200 of FIG. 2 at various stages of a second portion of a method of manufacturing according to some examples. The processing shown in FIGS. 6 through 11 shows, among other things, the formation of the gate structure G of the semiconductor device 200 of FIG. 2.

Referring to FIG. 6, one or more transition layers 104 are formed over and on a semiconductor substrate 102. A channel layer 106 is formed over and on the transition layer(s) 104, and a barrier layer 108 is formed over and on the channel layer 106. A gate layer 302 is formed over and on the barrier layer 108, and a silicon layer 304 is formed over and on the gate layer 302. Another conductive layer may be formed in the place of or with (e.g., over and on) the silicon layer 304. The transition layer(s) 104, channel layer 106, barrier layer 108, gate layer 302, and silicon layer 304 may be formed as described with respect to FIG. 3.

A sacrificial layer 602 is formed over and on the silicon layer 304 (or other conductive layer). The sacrificial layer 602 may be formed by using any appropriate deposition process, such as LPCVD, ALD, or the like. The sacrificial layer 602 may be or include any material that may be selectively etched relative to other layers. For example, the sacrificial layer may be a silicon nitride layer, a silicon dioxide layer, an aluminum oxide layer, or any other appropriate layer.

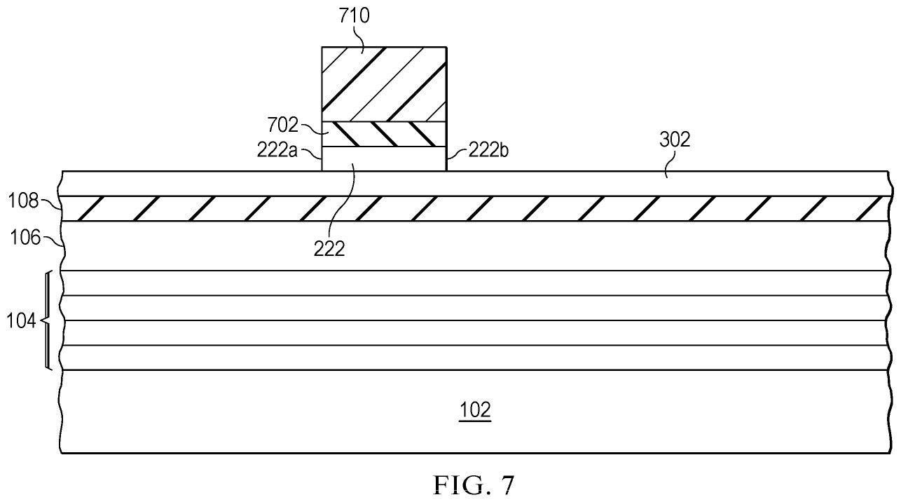

Referring to FIG. 7, the sacrificial layer 602 and the silicon layer 304 are patterned into a patterned sacrificial layer 702 and a patterned silicon layer 222, respectively. The sacrificial layer 602 and the silicon layer 304 may be patterned using appropriate photolithography and etch processes. For example, to pattern the sacrificial layer 602 and the silicon layer 304, a photoresist 710 is deposited (e.g., by spin-on) on or over the semiconductor substrate 102 (e.g., on or over the sacrificial layer 602) and patterned using photolithography. The photoresist 710 is patterned to remain in an area corresponding to an area where the silicon layer 222 of the gate structure G is to be formed. With the patterned photoresist 710, an etch process, such as an anisotropic etch like a RIE or the like, is performed, using the patterned photoresist 710 as a mask, to pattern the sacrificial layer 602 and the silicon layer 304 into the patterned sacrificial layer 702 and the patterned silicon layer 222. After the etch process, the photoresist 710 is removed, such as by ashing. Patterning as described with respect to FIG. 7 forms the sidewall surfaces 222a, 222b of the silicon layer 222.

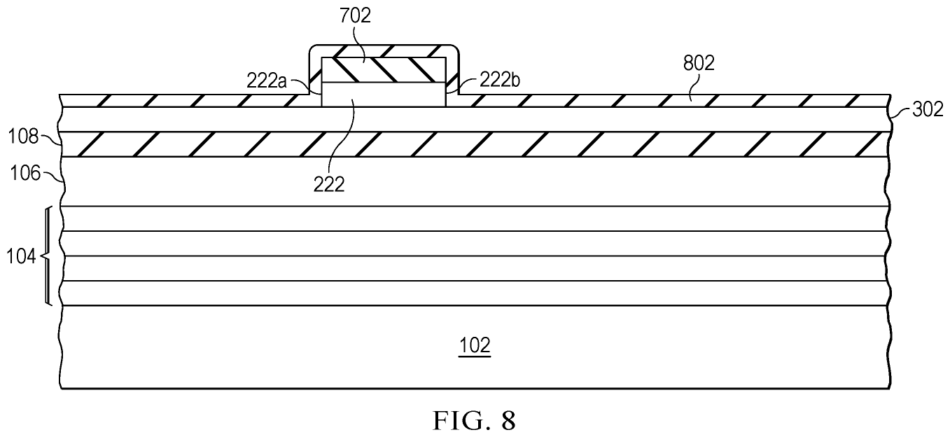

Referring to FIG. 8, a spacer layer 802 is formed over and on the sacrificial layer 702 and the gate layer 302 and along the sidewall surfaces 222a, 222b of the silicon layer 222 and sidewall surface of the sacrificial layer 702. The spacer layer 802 is conformally deposited over and on the gate layer 302, along the sidewall surfaces 222a, 222b of the silicon layer 222, along sidewall surfaces of the sacrificial layer 702, and over and on an upper surface of the sacrificial layer 702. The spacer layer 802 may be formed using any appropriate deposition process, such as PECVD, LPCVD, ALD, or the like.

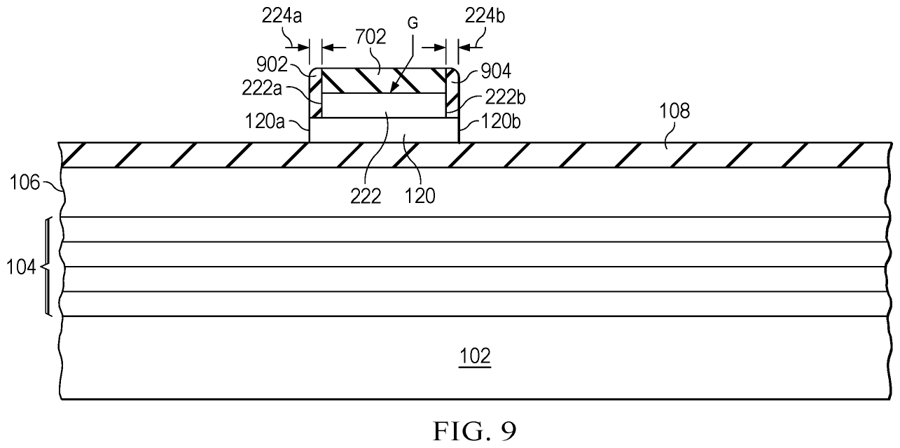

Referring to FIG. 9, the spacer layer 802 is anisotropically etched to form sidewall spacers 902, 904. Anisotropically etching the spacer layer 802 removes substantially horizontal portions of the spacer layer 802 such that vertical portions of the spacer layer 802 along sidewall surfaces remain as the sidewall spacers 902, 904. The sidewall spacer 902 is along the source-side sidewall surface 222a of the silicon layer 222 and corresponding sidewall surface of the sacrificial layer 702, and the sidewall spacer 904 is along the drain-side sidewall surface 222b of the silicon layer 222 and corresponding sidewall surface of the sacrificial layer 702.

The gate layer 302 is patterned into a patterned gate layer 120. The sacrificial layer 702 and sidewall spacers 902, 904 are used as a mask to pattern the gate layer 120. With the sacrificial layer 702 and sidewall spacers 902, 904 used as a mask, an anisotropic etch, such as a RIE, is performed to pattern the gate layer 302 into the patterned gate layer 120. Patterning as described with respect to FIG. 9 forms the sidewall surfaces 120a, 120b of the gate layer 120. As illustrated, the sidewall surfaces 120a, 120b of the gate layer 120 are laterally offset by lateral distances 224a, 224b from the sidewall surfaces 222a, 222b of the silicon layer 222. The lateral distances 224a, 224b correspond to lateral thicknesses of the sidewall spacers 902, 904, respectively.

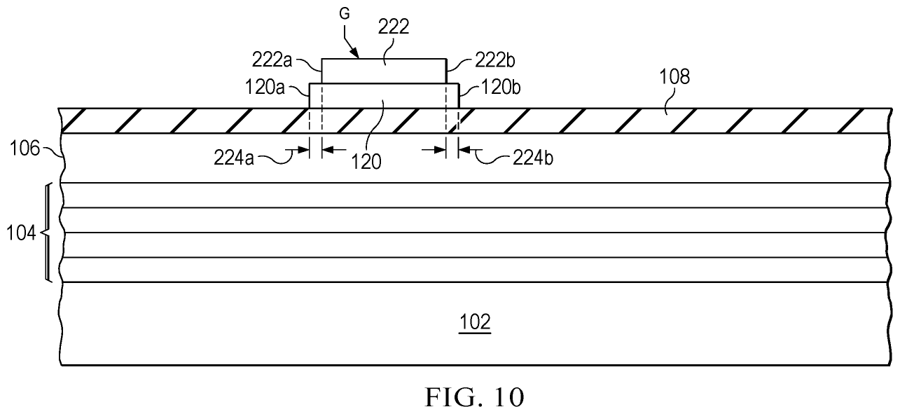

Referring to FIG. 10, the sacrificial layer 702 and sidewall spacers 902, 904 are removed. The sacrificial layer 702 and sidewall spacers 902, 904 may be removed using, for example, an isotropic etch (e.g., a wet etch) selective to the materials of the sacrificial layer 702 and sidewall spacers 902, 904.

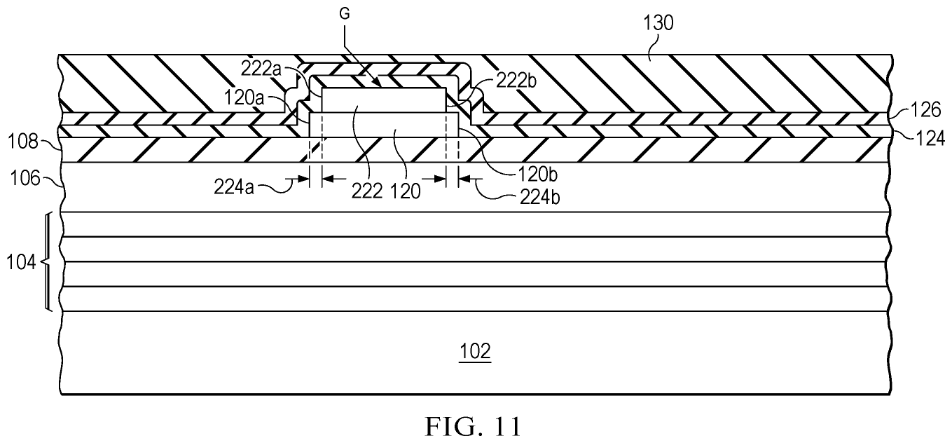

Referring to FIG. 11, a first conformal dielectric layer 124 is formed over and on the silicon layer 222 and barrier layer 108, along the sidewall surfaces 120a, 120b, 222a, 222b of the gate layer 120 and silicon layer 222, and over and on an upper surface of the gate layer 120 where the sidewall surfaces 222a, 222b of the silicon layer 222 are laterally offset from the sidewall surfaces 120a, 120b of the gate layer 120. The first conformal dielectric layer 124 is conformally deposited over and on the barrier layer 108, along the sidewall surfaces 120a, 120b, 222a, 222b of the gate layer 120 and silicon layer 222, over and on the upper surface of the gate layer 120, and over and on an upper surface of the silicon layer 222. A second conformal dielectric layer 126 is formed over and on the first conformal dielectric layer 124. A first dielectric layer 130 is formed over and on the second conformal dielectric layer 126. The first conformal dielectric layer 124, the second conformal dielectric layer 126, and the first dielectric layer 130 may be formed as described above with respect to FIG. 5.

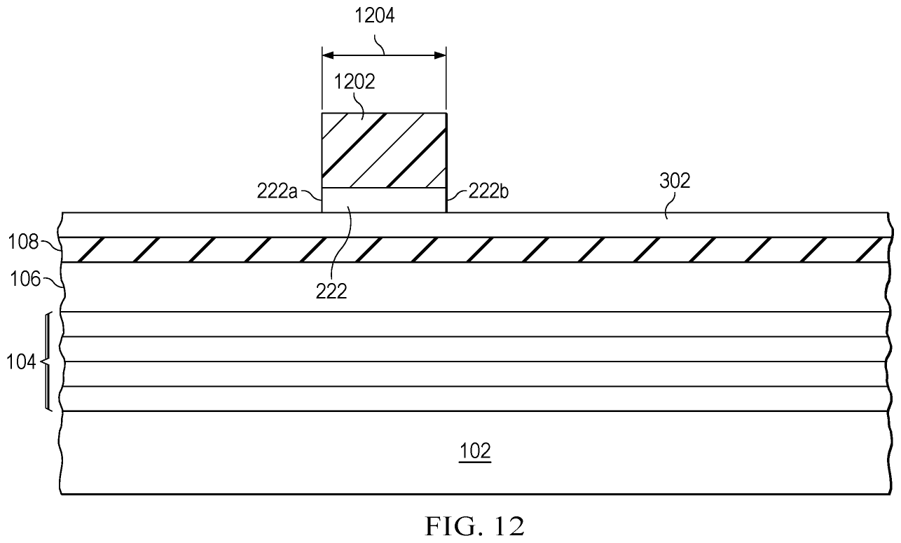

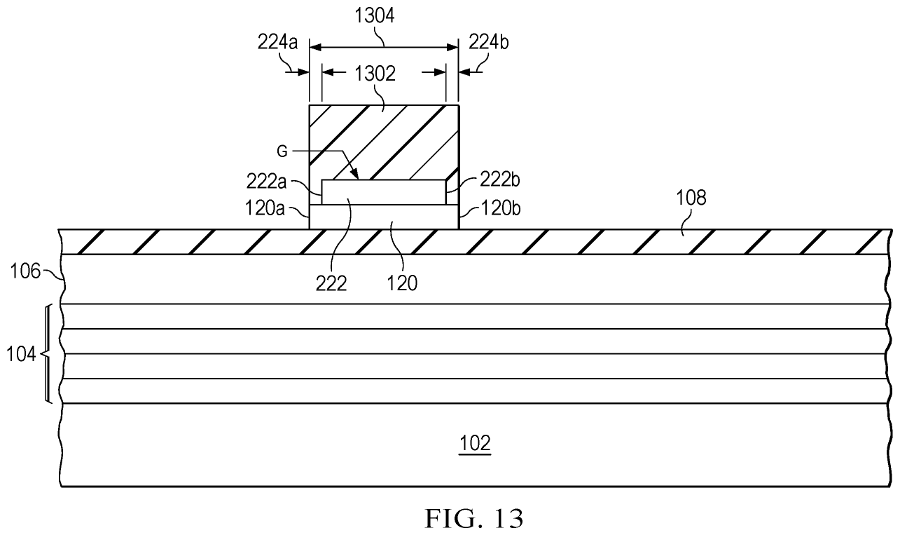

FIGS. 12 and 13 illustrate cross-sectional views of the semiconductor device 200 of FIG. 2 at various stages of a third portion of a method of manufacturing according to some examples. The processing shown in FIGS. 12 and 13 shows, among other things, the formation of the gate structure G of the semiconductor device 200 of FIG. 2.

Processing proceeds as described with respect to FIG. 3. Referring to FIG. 12, the silicon layer 304 is patterned into a patterned silicon layer 222. The silicon layer 304 may be patterned using appropriate photolithography and etch processes. For example, to pattern the silicon layer 304, a photoresist 1202 is deposited (e.g., by spin-on) on or over the semiconductor substrate 102 (e.g., on or over the silicon layer 304) and patterned using photolithography. The photoresist 1202 is patterned to remain in an area corresponding to an area where the silicon layer 222 of the gate structure G is to be formed. With the patterned photoresist 1202, an etch process, such as an anisotropic etch like a RIE or the like, is performed, using the patterned photoresist 1202 as a mask, to pattern the silicon layer 304 into the patterned silicon layer 222. After the etch process, the photoresist 1202 is removed, such as by ashing. Patterning as described with respect to FIG. 12 forms the sidewall surfaces 222a, 222b of the silicon layer 222. Further, the photoresist 1202 has a lateral dimension 1204, which corresponds to a lateral dimension between the sidewall surfaces 222a, 222b of the silicon layer 222.

Referring to FIG. 13, the gate layer 302 is patterned into a patterned gate layer 120. The gate layer 302 may be patterned using appropriate photolithography and etch processes. For example, to pattern the gate layer 302, a photoresist 1302 is deposited (e.g., by spin-on) on or over the semiconductor substrate 102 (e.g., on or over the gate layer 302 and the patterned silicon layer 222) and patterned using photolithography. The photoresist 1302 is patterned to remain in an area corresponding to an area where the gate layer 120 of the gate structure G is to be formed. With the patterned photoresist 1302, an etch process, such as an anisotropic etch like a RIE or the like, is performed, using the patterned photoresist 1302 as a mask, to pattern the gate layer 302 into the patterned gate layer 120. After the etch process, the photoresist 1302 is removed, such as by ashing. Patterning as described with respect to FIG. 13 forms the sidewall surfaces 120a, 120b of the gate layer 120. Further, the photoresist 1302 has a lateral dimension 1304, which corresponds to a lateral dimension between the sidewall surfaces 120a, 120b of the gate layer 120. The lateral dimension 1304 of the photoresist 1302 of FIG. 13 is greater than the lateral dimension 1204 of the photoresist 1202 of FIG. 12. As illustrated, the sidewall surfaces 120a, 120b of the gate layer 120 are laterally offset by lateral distances 224a, 224b from the sidewall surfaces 222a, 222b of the silicon layer 222. The lateral distances 224a, 224b may correspond to lateral thicknesses of the sidewall spacers 902, 904, respectively. In some examples, the lateral distances 224a, 224b are different from each other. Processing then continues as described above with respect to FIG. 11.

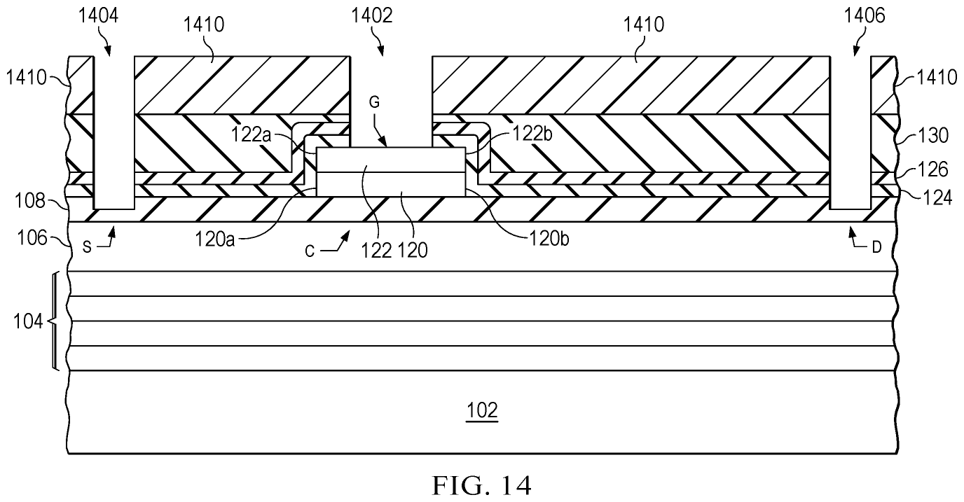

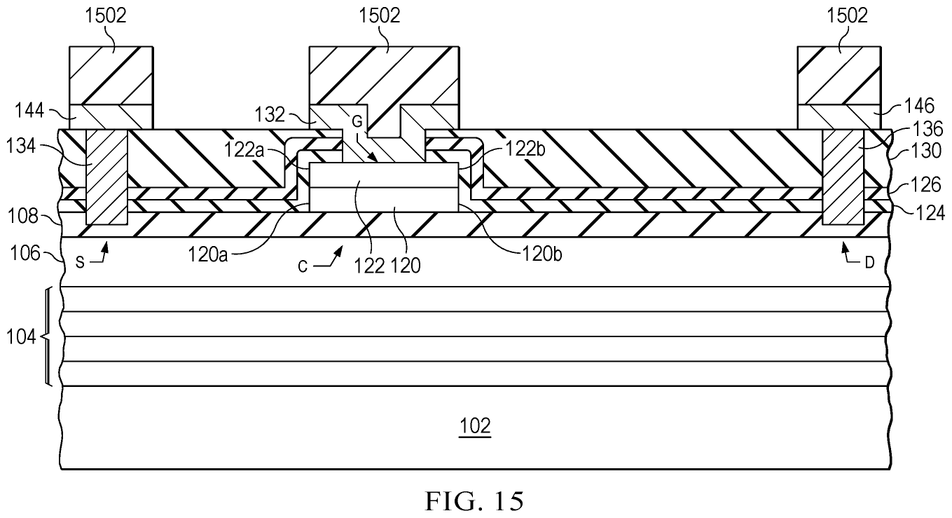

FIGS. 14 and 15 illustrate cross-sectional views of a semiconductor device at various stages of a fourth portion of a method of manufacturing according to some examples.

The processing shown in FIGS. 14 and 15 shows, among other things, the formation of the contacts 132, 134, 136 through the dielectric layers 130, 124, 126. The processing shown in FIGS. 14 and 15 is shown following the first portion of the method of FIGS. 3 through 5 to implement the semiconductor device 100 of FIG. 1. In other examples, the processing shown in FIGS. 14 and 15 may be implemented following the second portion of the method of FIGS. 6 through 11 or the third portion of the method of FIGS. 12 and 13 to implement the semiconductor device 200 of FIG. 2.

Referring to FIG. 14, contact openings 1402, 1404, 1406 are formed through the first dielectric layer 130, the second conformal dielectric layer 126, and the first conformal dielectric layer 124. The contact opening 1402 is formed to the silicon layer 122 of the gate structure G. The contact opening 1404 is formed to and into the barrier layer 108 at the source region S, and the contact opening 1406 is formed to and into the barrier layer 108 at the drain region D. The contact openings 1402, 1404, 1406 may be formed using appropriate photolithography and etch processes. For example, to form the contact openings 1402, 1404, 1406, a photoresist 1410 is deposited (e.g., by spin-on) on or over the semiconductor substrate 102 (e.g., on or over the first dielectric layer 130) and patterned using photolithography. The photoresist 1410 is patterned to expose areas where the contact openings 1402, 1404, 1406 are to be formed. With the patterned photoresist 1410 being used as a mask, an etch process, such as an anisotropic etch like a RIE or the like, is performed to form the contact openings 1402, 1404, 1406. After the etch process, the photoresist 1410 is removed, such as by ashing.

Referring to FIG. 15, one or more metals are deposited into the contact openings 1402, 1404, 1406 and over and on an upper surface of the first dielectric layer 130. The one or more metals deposited into the contact openings 1402, 1404, 1406 form the gate contact 132, source contact 134, and drain contact 136, respectively. The metal(s) over the upper surface of the first dielectric layer 130 are patterned into the gate contact 132 and the metal lines 144, 146. For example, to pattern the metal(s) over the upper surface of the first dielectric layer 130, a photoresist 1502 is deposited (e.g., by spin-on) on or over the semiconductor substrate 102 (e.g., on or over the metal(s)) and patterned using photolithography. The photoresist 1502 is patterned to remain in areas corresponding to areas where the gate contact 132 and the metal lines 144, 146 are to be formed. With the patterned photoresist 1502 being used as a mask, an etch process, such as an anisotropic etch like a RIE or the like, is performed to pattern the metal(s) into the gate contact 132 and the metal lines 144, 146. After the etch process, the photoresist 1502 is removed, such as by ashing.

Referring to FIG. 1 or 2, the second dielectric layer 150 is formed over and on the first dielectric layer 130, the gate contact 132, and the metal lines 144, 146. The second dielectric layer 150 may be deposited using any appropriate deposition process, such as PECVD or the like. The second dielectric layer 150 may be planarized, such as by a CMP.

The metal vias 154, 156 are formed through the second dielectric layer 150 to the metal lines 144, 146, respectively. The metal field plate 164 and metal line 166 are formed over and on the second dielectric layer 150. Openings may be formed through the second dielectric layer 150 to the metal lines 144, 146 using appropriate photolithography and etching processes. A metal(s) of the metal vias 154, 156, metal field plate 164, and metal line 166 are deposited over the second dielectric layer 150 and in the openings through the second dielectric layer 150. The metal(s) may be deposited using an appropriate deposition process(es), such as chemical vapor deposition (CVD), physical vapor deposition (PVD), e-beam evaporation, or the like. The metal(s) may be patterned into the metal field plate 164 and metal line 166 using appropriate photolithography and etching processes. The metal(s) underlying the metal field plate 164 and metal line 166 and in the respective openings through the second dielectric layer 150 form the metal vias 154, 156.

The third dielectric layer 170 is formed over and on the second dielectric layer 150 and the metal field plate 164 and metal line 166. The third dielectric layer 170 may be deposited using any appropriate deposition process, such as PECVD or the like. The third dielectric layer 170 may be planarized, such as by a CMP.

The metal via 174 is formed through the third dielectric layer 170 to the metal field plate 164. The metal field plate 176 is formed over and on the third dielectric layer 170. An opening may be formed through the third dielectric layer 170 to the metal field plate 164 using appropriate photolithography and etching processes. A metal(s) of the metal via 174 and metal field plate 176 are deposited over the third dielectric layer 170 and in the openings through the third dielectric layer 170. The metal(s) may be deposited using an appropriate deposition process(es), such as CVD, PVD, e-beam evaporation, or the like. The metal(s) may be patterned into the metal field plate 176 using appropriate photolithography and etching processes. The metal(s) underlying the metal field plate 176 and in the opening through the third dielectric layer 170 form the metal via 174.

The processing shown by FIGS. 14 and 15 illustrates how the gate contact 132, source contact 134, and drain contact 136 may be formed from a same metal(s) using one lithography mask (e.g., for patterning the photoresist 1410) for forming the contact openings 1402, 1404, 1406 in which the contacts 132, 134, 136 are formed and using one lithography mask (e.g., for patterning the photoresist 1502) for patterning the gate contact 132 and metal lines 144, 146. Using such lithography masks may reduce processing steps.

Other examples described below illustrate how different lithography masks may be implemented. Photolithography and etch processes are described briefly subsequently, where appropriate, in view of the previous description.

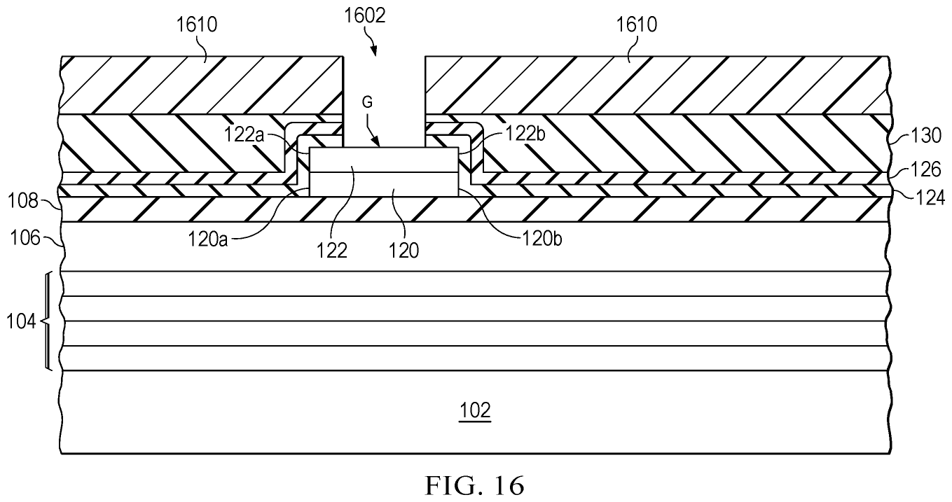

FIGS. 16 through 19 illustrate cross-sectional views of a semiconductor device at various stages of a fifth portion of a method of manufacturing according to some examples. The processing shown in FIGS. 16 through 19 shows, among other things, the formation of the contacts 132, 134, 136 through the dielectric layers 130, 124, 126. The processing shown in FIGS. 16 through 19 is shown following the first portion of the method of FIGS. 3 through 5 to implement the semiconductor device 100 of FIG. 1. In other examples, the processing shown in FIGS. 16 through 19 may be implemented following the second portion of the method of FIGS. 6 through 11 or the third portion of the method of FIGS. 12 and 13 to implement the semiconductor device 200 of FIG. 2.

Referring to FIG. 16, a contact opening 1602 is formed through the first dielectric layer 130, the second conformal dielectric layer 126, and the first conformal dielectric layer 124. The contact opening 1602 is formed to the silicon layer 122 of the gate structure G. The contact opening 1602 may be formed using appropriate photolithography and etch processes (e.g., using a photoresist 1610).

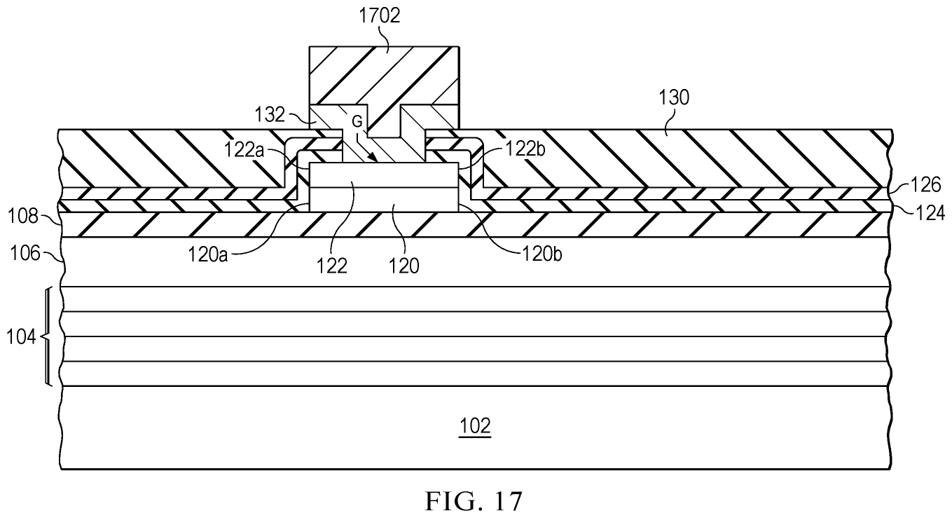

Referring to FIG. 17, one or more metals are deposited into the contact opening 1402 and over and on an upper surface of the first dielectric layer 130. The one or more metals deposited into the contact opening 1602 form the gate contact 132. The metal(s) over the upper surface of the first dielectric layer 130 are patterned into the gate contact 132. The gate contact 132 may be patterned using appropriate photolithography and etch processes (e.g., using a photoresist 1702).

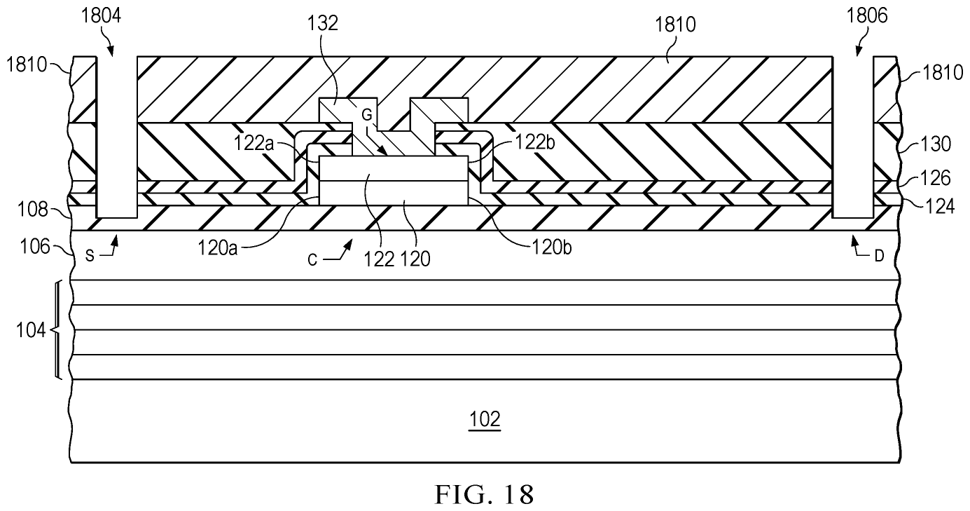

Referring to FIG. 18, contact openings 1804, 1806 are formed through the first dielectric layer 130, the second conformal dielectric layer 126, and the first conformal dielectric layer 124. The contact opening 1804 is formed to and into the barrier layer 108 at the source region S, and the contact opening 1806 is formed to and into the barrier layer 108 at the drain region D. The contact openings 1804, 1806 may be formed using appropriate photolithography and etch processes (e.g., using a photoresist 1810).

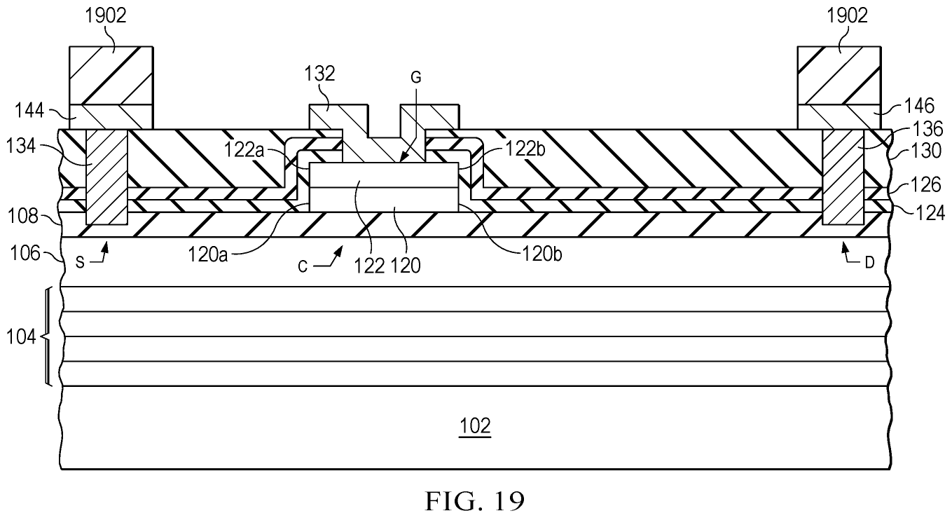

Referring to FIG. 19, one or more metals are deposited into the contact openings 1804, 1806 and over and on an upper surface of the first dielectric layer 130. The one or more metals deposited into the contact openings 1804, 1806 form the source contact 134 and drain contact 136, respectively. The metal(s) over the upper surface of the first dielectric layer 130 are patterned into the metal lines 144, 146. The metal lines 144, 146 may be patterned using appropriate photolithography and etch processes (e.g., using a photoresist 1902). The metal(s) used to form the metal lines 144, 146 may be deposited on the gate contact 132. The photolithography and etch processes may remove the metal(s) deposited on the gate contact 132, and/or the metal(s) may remain after the photolithography and etch processes. Subsequently, processing continues as described above with respect to FIG. 1 or 2.

The processing shown by FIGS. 16 through 19 illustrate how the gate contact 132 may be formed from metal(s) that may be different from or the same as the metal(s) of the source contact 134 and drain contact 136. Further, the processing shown by FIGS. 16 through 19 illustrate using two lithography masks (e.g., for patterning the photoresists 1610, 1810) for forming the contact openings 1602, 1804, 1806 in which the contacts 132, 134, 136 are formed and using two lithography masks (e.g., for patterning the photoresists 1702, 1902) for patterning the gate contact 132 and metal lines 144, 146. Although the gate contact 132 is illustrated as being formed in FIGS. 16 and 17 before the source contact 134 and drain contact 136 are formed in FIGS. 18 and 19, the source contact 134 and drain contact 136 may be formed before the gate contact 132 by performing the processing of FIGS. 18 and 19 before the processing of FIGS. 16 and 17. Forming the source contact 134 and drain contact 136 before the gate contact 132 may prevent some spiking from the gate contact 132 into the silicon layer 122 and/or gate layer 120 during high temperature processing, which may occur for forming ohmic contacts such as the source contact 134 and the drain contact 136.

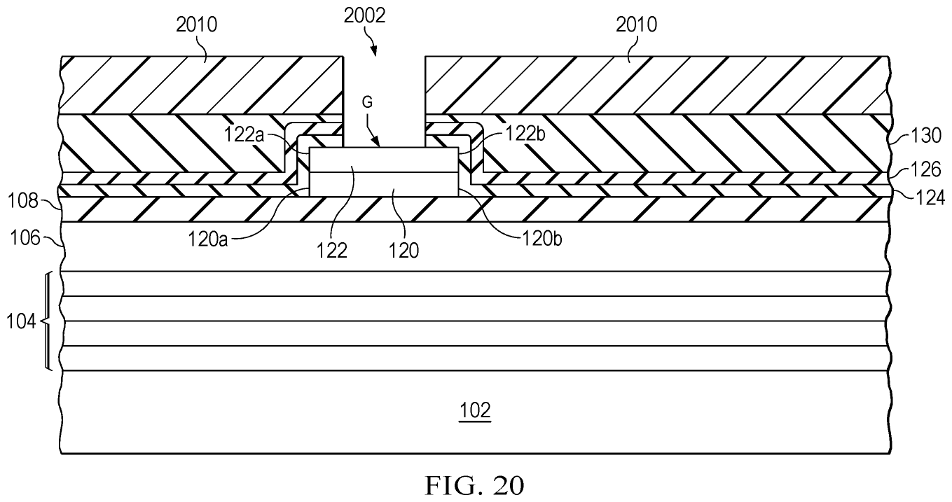

FIGS. 20 through 22 illustrate cross-sectional views of a semiconductor device at various stages of a sixth portion of a method of manufacturing according to some examples. The processing shown in FIGS. 20 through 22 shows, among other things, the formation of the contacts 132, 134, 136 through the dielectric layers 130, 124, 126. The processing shown in FIGS. 20 through 22 is shown following the first portion of the method of FIGS. 3 through 5 to implement the semiconductor device 100 of FIG. 1. In other examples, the processing shown in FIGS. 20 through 22 may be implemented following the second portion of the method of FIGS. 6 through 11 or the third portion of the method of FIGS. 12 and 13 to implement the semiconductor device 200 of FIG. 2.

Referring to FIG. 20, a contact opening 2002 is formed through the first dielectric layer 130, the second conformal dielectric layer 126, and the first conformal dielectric layer 124. The contact opening 2002 is formed to the silicon layer 122 of the gate structure G. The contact opening 2002 may be formed using appropriate photolithography and etch processes (e.g., using a photoresist 2010).

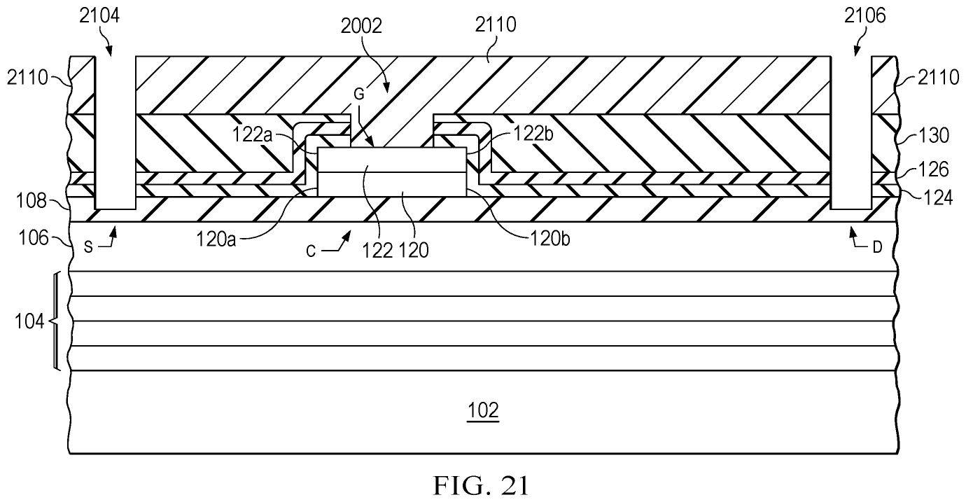

Referring to FIG. 21, contact openings 2104, 2106 are formed through the first dielectric layer 130, the second conformal dielectric layer 126, and the first conformal dielectric layer 124. The contact opening 2104 is formed to and into the barrier layer 108 at the source region S, and the contact opening 2106 is formed to and into the barrier layer 108 at the drain region D. The contact openings 2104, 2106 may be formed using appropriate photolithography and etch processes (e.g., using a photoresist 2110).

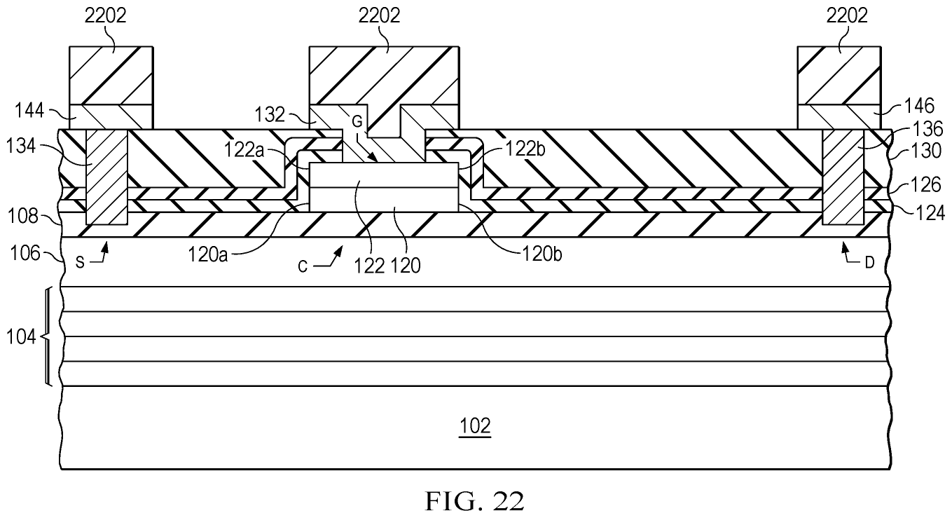

Referring to FIG. 22, one or more metals are deposited into the contact openings 2002, 2104, 2106 and over and on an upper surface of the first dielectric layer 130. The one or more metals deposited into the contact openings 2002, 2104, 2106 form the gate contact 132, source contact 134, and drain contact 136, respectively. The metal(s) over the upper surface of the first dielectric layer 130 are patterned into the gate contact 132 and the metal lines 144, 146. The gate contact 132 and the metal lines 144, 146 may be patterned using appropriate photolithography and etch processes (e.g., using a photoresist 2202). Subsequently, processing continues as described above with respect to FIG. 1 or 2.

The processing shown by FIGS. 20 through 22 illustrate how the gate contact 132, source contact 134, and drain contact 136 may be formed from a same metal(s). Further, the processing shown by FIGS. 20 through 22 illustrate using two lithography masks (e.g., for patterning the photoresists 2010, 2110) for forming the contact openings 2002, 2104, 2106 in which the contacts 132, 134, 136 are formed and using one lithography mask (e.g., for patterning the photoresist 2202) for patterning the gate contact 132 and metal lines 144, 146.

Although various examples have been described in detail, it should be understood that various changes, substitutions, and alterations can be made therein without departing from the scope defined by the appended claims.

What is claimed is:

1. A semiconductor device, comprising:
a channel layer over a semiconductor substrate;
a barrier layer over the channel layer;
a gate layer over the barrier layer; and
a silicon layer over and contacting the gate layer.

2. The semiconductor device of claim 1, wherein the silicon layer includes polysilicon doped with a p-type dopant.

3. The semiconductor device of claim 2, wherein the polysilicon doped with the p-type dopant forms a Schottky junction with the gate layer.

4. The semiconductor device of claim 2, wherein a concentration of the p-type dopant in the silicon layer is 1×10²⁰ cm⁻³ or greater.

5. The semiconductor device of claim 1, wherein the gate layer includes gallium nitride (GaN).

6. The semiconductor device of claim 1, wherein:
the gate layer is doped with a first dopant of a conductivity type;
the silicon layer is doped with a second dopant of the conductivity type; and
a first concentration of the first dopant in the gate layer is less than 50% of a second concentration of the second dopant in the silicon layer.

7. The semiconductor device of claim 1, wherein:
the gate layer includes gallium nitride (GaN) doped with a p-type dopant, wherein the p-type dopant includes magnesium, carbon, zinc, or a combination thereof; and
the silicon layer includes polysilicon doped with boron, wherein a concentration of the boron in the polysilicon is at least two (2) times greater than a concentration of the p-type dopant in the gallium nitride (GaN).

8. The semiconductor device of claim 1, wherein:
the gate layer includes gallium nitride (GaN) doped with a p-type dopant, wherein the p-type dopant includes magnesium, carbon, zinc, or a combination thereof, a concentration of the p-type dopant in the gate layer being equal to or less than 1×10²¹ cm⁻³; and
the silicon layer includes polysilicon doped with boron, a concentration of the boron in the silicon layer being equal to or greater than 1×10¹⁹ cm⁻³.

9. The semiconductor device of claim 1, further comprising a gate contact over and contacting the silicon layer.

10. The semiconductor device of claim 9, wherein the gate contact includes a metal that forms an ohmic junction with the silicon layer.

11. The semiconductor device of claim 9, further comprising:
a source contact electrically coupled to the channel layer; and
a drain contact electrically coupled to the channel layer, wherein the gate layer and the silicon layer are laterally between the source contact and the drain contact, wherein the source contact and the drain contact include a same metal as the gate contact.

12. The semiconductor device of claim 11, wherein the metal includes an aluminum-based metal, a copper-based metal, or a tungsten-based metal.

13. The semiconductor device of claim 9, further comprising:
a source contact electrically coupled to the channel layer; and
a drain contact electrically coupled to the channel layer, wherein the gate layer and the silicon layer are laterally between the source contact and the drain contact, wherein the source contact and the drain contact include a different metal than the gate contact.

14. The semiconductor device of claim 13, wherein:
the source contact and the drain contact include an aluminum-based metal, a copper-based metal, or a tungsten-based metal; and
the gate contact includes titanium nitride (TiN), titanium tungsten (TiW), nickel (Ni), platinum (Pt), tantalum nitride (TaN), gold (Au), iridium (Ir), tantalum (Ta), or a combination thereof.

15. The semiconductor device of claim 9, further comprising a dielectric layer on an upper surface of the barrier layer and over the gate layer and the silicon layer, the gate contact being through the dielectric layer.

16. The semiconductor device of claim 1, further comprising:
a source contact electrically coupled to the channel layer; and
a drain contact electrically coupled to the channel layer, wherein the gate layer and the silicon layer are laterally between the source contact and the drain contact, respective sidewall surfaces of the gate layer and the silicon layer proximate to a first one of the source contact and the drain contact being vertically aligned.

17. The semiconductor device of claim 16, wherein respective sidewall surfaces of the gate layer and the silicon layer proximate to a second one of the source contact and the drain contact different from the first one are vertically aligned.

18. The semiconductor device of claim 1, further comprising:
a source contact electrically coupled to the channel layer; and
a drain contact electrically coupled to the channel layer, wherein the gate layer and the silicon layer are laterally between the source contact and the drain contact, respective sidewall surfaces of the gate layer and the silicon layer proximate a first one of the source contact and the drain contact being laterally offset from each other.

19. The semiconductor device of claim 18, wherein respective sidewall surfaces of the gate layer and the silicon layer proximate a second one of the source contact and the drain contact different from the first one are laterally offset from each other.

20. A method, comprising:
forming a channel layer over a semiconductor substrate;
forming a barrier layer over the channel layer;
forming a gate layer over the barrier layer; and
forming a silicon layer over and contacting the gate layer.

21. The method of claim 20, wherein forming the gate layer and forming the silicon layer includes patterning the gate layer and the silicon layer using a same mask.

22. The method of claim 20, wherein:
forming the silicon layer includes:
depositing the silicon layer on the gate layer; and
patterning the silicon layer using a mask; and
forming the gate layer includes:
depositing the gate layer on the barrier layer;
depositing a spacer layer on the patterned silicon layer;
anisotropically etching the spacer layer to form spacers on respective sidewall surfaces of the patterned silicon layer; and
patterning the gate layer using the spacers as a mask.

23. The method of claim 20, wherein:
forming the silicon layer includes:
depositing the silicon layer on the gate layer; and
patterning the silicon layer using a first mask having a first lateral dimension; and
forming the gate layer includes:
depositing the gate layer on the barrier layer; and
patterning the gate layer using a second mask having a second lateral dimension greater than the first lateral dimension, the second mask being on the patterned silicon layer while patterning the gate layer.

24. A semiconductor device, comprising:
a high electron mobility transistor (HEMT) comprising:
a channel layer over a semiconductor substrate;
a barrier layer over the channel layer; and
a gate structure over the barrier layer, the gate structure comprising:
a semiconductor layer; and
a silicon layer over and contacting the semiconductor layer, the semiconductor layer including a semiconductor material different from silicon.

25. The semiconductor device of claim 24, wherein:
the semiconductor layer includes gallium nitride (GaN) doped with a p-type dopant;
the p-type dopant includes magnesium, carbon, zinc, or a combination thereof;
the silicon layer includes polysilicon doped with boron; and
a concentration of the boron in the polysilicon is two (2) times or greater than a concentration of the p-type dopant in the gallium nitride (GaN).

26. The semiconductor device of claim 24, wherein:
the semiconductor layer includes gallium nitride (GaN) doped with a p-type dopant;
the p-type dopant includes magnesium, carbon, zinc, or a combination thereof;
a concentration of the p-type dopant in the semiconductor layer is equal to or less than 1×10²¹ cm⁻³;
the silicon layer includes polysilicon doped with boron; and
a concentration of the boron in the polysilicon is equal to or greater than 1×10¹⁹ cm⁻³.
